(19) United States
(12) Patent Application Publication
(10) Pub. No.: US 2026/0242212 A1
(43) Pub. Date: Aug. 20, 2026

(54) MICRO-ELECTRO-MECHANICAL SYSTEM PACKAGE

(71) Applicant: Vanguard International Semiconductor Corporation, Hsinchu (TW)

(72) Inventors: ROHIT PULIKKAL KIZHAKKEYIL, Singapore (SG); RAKESH CHAND, Singapore (SG); Tze Sheong Neoh, Johor Bahru (MY); GUOFU ZHOU, Singapore (SG); HUP FONG TAN, Singapore (SG); RAMACHANDRAMURTHY PRADEEP YELEHANKA, Singapore (SG)

(73) Assignee: Vanguard International Semiconductor Corporation, Hsinchu (TW)

(21) Appl. No.: 19/056,776

(22) Filed: Feb. 19, 2025

(51) Int. Cl. B81B 7/00; B81C 1/00

(52) U.S. Cl. CPC B81B 7/007; B81C 1/0023; B81B 2201/0235; B81B 2201/0242; B81B 2203/0315; B81B 2207/012; B81B 2207/07; B81B 2207/094; B81C 2201/0132; B81C 2201/016; B81C 2201/019; B81C 2203/0172; B81C 2203/037; B81C 2203/0792

(57) ABSTRACT

A MEMS package includes an interconnect layer disposed on a first substrate. The interconnect layer includes a second metal layer disposed below and thicker than a first metal layer. A first dielectric layer is disposed on the first metal layer. A second dielectric layer is disposed between the first and second metal layers. An opening passes through the first and second dielectric layers to expose a portion of the second metal layer. A MEMS device layer is bonded on the interconnect layer. A second substrate includes a cavity and is bonded on the MEMS device layer.

### BACKGROUND OF THE INVENTION

### 1. Field of The Invention

The present disclosure relates generally to micro-electro-mechanical system (MEMS) packages, and more particularly to MEMS packages including a thicker bond pad in an interconnect layer for wire bonding, and fabrication methods thereof.

### 2. Description of The Prior Art

Micro-electro-mechanical systems (MEMS) devices are microscopic devices that integrate mechanical and electrical components to sense physical quantities and/or to interact with the surrounding environment. In recent years, MEMS devices are used as micro-sensors such as motion sensors, pressure sensors, acceleration sensors, etc., and have become widespread in many electronic products, such as tablet computers, automobiles, and smartphones. As the MEMS devices are extensively used in consumer electronics, they are also becoming more cost-sensitive. However, conventional MEMS packages cannot fully satisfy the requirements for cost reduction and device performance.

### SUMMARY OF THE INVENTION

In view of this, the present disclosure provides micro-electro-mechanical system (MEMS) packages and fabrication methods thereof to reduce cost while maintaining performance. The cost of the MEMS packages is reduced by replacing gold wire with copper wire. The performance of the MEMS packages is maintained by using a thick bond pad in an interconnect layer for wire bonding.

According to an embodiment of the present disclosure, a MEMS package is provided and includes a first substrate, an interconnect layer, a MEMS device layer and a second substrate. The interconnect layer is disposed on the first substrate. The interconnect layer includes a first metal layer, a second metal layer, a first dielectric layer, a second dielectric layer and an opening. The second metal layer is disposed below and thicker than the first metal layer. The first dielectric layer is disposed on the first metal layer. The second dielectric layer is disposed between the first metal layer and the second metal layer. The opening passes through the first dielectric layer and the second dielectric layer to expose a portion of the second metal layer. The MEMS device layer is bonded to the interconnect layer. The second substrate includes a cavity and is bonded to the MEMS device layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a schematic cross-sectional view of a MEMS package according to one embodiment of the present disclosure.

FIG. 2 is a schematic cross-sectional view of a MEMS package according to another embodiment of the present disclosure.

FIGS. 3, 4, 5, 6, 7, and 8 are schematic cross-sectional views of some stages of a method of fabricating a MEMS package according to one embodiment of the present disclosure.

FIG. 9 and FIG. 10 are schematic cross-sectional views of some intermediate stages of a method of fabricating a MEMS package according to another embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “under”, “on”, “over”, “above”, “upper”, “bottom”, “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as "below" and/or "under" other elements or features would then be oriented "above" and/or "over" the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as "first", "second", and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that may vary as desired.

Furthermore, as disclosed herein, the terms "coupled to" and "electrically connected to" include any directly and indirectly electrical connecting means. Therefore, if it is described in this document that a first component is coupled or electrically connected to a second component, it means that the first component may be directly connected to the second component, or may be indirectly connected to the second component through other components or other connecting means.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

The present disclosure is directed to MEMS packages and fabrication methods thereof. The MEMS packages includes a thick bond pad in an interconnect layer for copper wire bonding. The interconnect layer includes a second metal layer (also referred to as a second-to-last metal layer) disposed below a first metal layer (also referred to as a top metal layer). The second metal layer is thicker than the first metal layer, and the thick bond pad is provided from the second metal layer. The cost of the MEMS packages is reduced by replacing gold wire with copper wire. The thick bond pad can provide good wire bonding for copper wire without increasing the thickness of the first metal layer. Therefore, the overall performance of the MEMS packages, such as eutectic bonding quality, electrode gap control and device sensitivity, are maintained without increasing the complexity of fabricating the interconnect layer on complementary metal-oxide-semiconductor (CMOS) wafer.

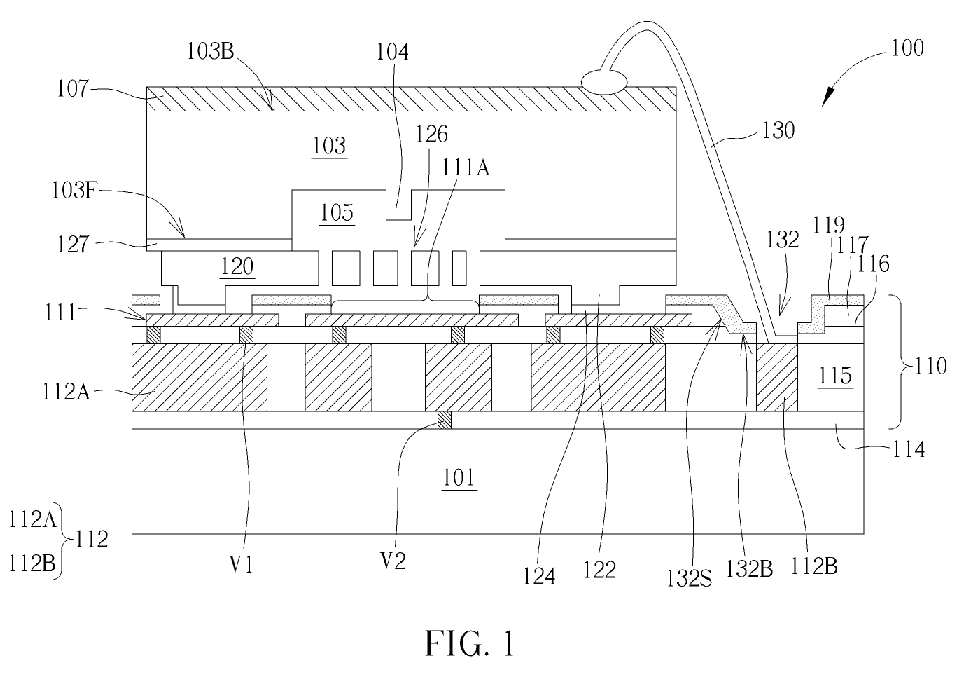

FIG. 1 is a schematic cross-sectional view of a MEMS package 100 according to one embodiment of the present disclosure. The MEMS package 100 includes a first substrate 101, an interconnect layer 110, a MEMS device layer 120 and a second substrate 103. The first substrate 101 may be a silicon wafer and includes multiple CMOS transistors or other elements formed therein. The interconnect layer 110 is disposed on the first substrate 101. The interconnect layer 110 includes multiple metal layers, multiple inter-metal dielectric (IMD) layers, and multiple vias in the IMD layers to connect two metal layers. The metal layers at least include a first metal layer 111 and a second metal layer 112. The IMD layers at least include a first dielectric layer 117, a second dielectric layer 116, a third dielectric layer 115 and a fourth dielectric layer 114. The vias at least include vias V1 and vias V2. In addition, the interconnect layer 110 includes a passivation layer 119 on the first dielectric layer 117.

The first metal layer 111 is a top metal layer, and the second metal layer 112 is a second-to-last metal layer disposed below the first metal layer 111. Moreover, the second metal layer 112 is thicker than the first metal layer 111. The thickness of the second metal layer 112 may be 2 to 7 times the thickness of the first metal layer 111. In some embodiments, the thickness of the second metal layer 112 is, for example, greater than about 0.9 µm and less than about 5 µm. The thickness of the first metal layer 111 is, for example, less than about 1 µm and greater than about 0.5 µm. In other embodiments, the thickness of the first metal layer 111 is, for example, less than about 0.9 µm and greater than about 0.3 µm. In one embodiment, the second metal layer 112 may have a uniform thickness in the interconnect layer 110. A portion 112B of the second metal layer 112 includes a thick bond pad for copper wire bonding. The first metal layer 111 is not disposed directly above the portion 112B of the second metal layer 112. In another embodiment, the second metal layer 112 may have a thickest part for a bond pad in the area of portion 112B, and other portions of the second metal layer 112 have different thicknesses greater than that of the first metal layer 111. In addition, other portions 112A of the second metal layer 112 are electrically coupled to the first metal layer 111 through the vias V1, and electrically coupled to the CMOS transistors or other elements in the first substrate 101 through the vias V2. Therefore, the interconnect layer 110 is electrically coupled to the CMOS transistors in the first substrate 101. In some embodiments, the compositions of the first metal layer 111 and the second metal layer 112 may be aluminum-copper (AlCu) alloy or aluminum (Al). The first metal layer 111 and the second metal layer 112 may have the same composition. The composition of the vias V1 and V2 may be tungsten (W), but not limited thereto.

The first dielectric layer 117 is disposed on and covers the first metal layer 111. The passivation layer 119 is disposed on the first dielectric layer 117. The second dielectric layer 116 is disposed between the first metal layer 111 and the second metal layer 112. The vias V1 are formed in the second dielectric layer 116. An opening 132 is formed in the interconnect layer 110 to pass through the first dielectric layer 117, the second dielectric layer 116 and the passivation layer 119, thereby exposing the portion 112B of the second metal layer 112 to provide a thick bond pad for wire bonding. Furthermore, in this embodiment, the passivation layer 119 is conformally extended on the sidewalls 132S and a portion 132B of the bottom surface of the opening 132. The exposed surface of the portion 112B of the second metal layer 112 is lower than the portion 132B of the bottom surface of the opening 132. In some embodiments, the composition of the passivation layer 119 may be silicon oxide or silicon nitride. The multiple IMD layers of the interconnect layer 110 may have the same composition, for example, silicon oxide.

As shown in FIG. 1, the MEMS device layer 120 is bonded to the interconnect layer 110. The MEMS device layer 120 includes a seal ring 122 bonded to the first metal layer 111 with a eutectic bonding material 124. The seal ring 122 is a standoff structure protruding towards the interconnect layer 110. The seal ring 122 is integrated into and has the same composition as the MEMS device layer 120. In some embodiments, the first metal layer 111 may be an aluminum (Al) layer or an aluminum-copper (AlCu) alloy layer, and a bonding layer of germanium (Ge) may be deposited on the seal ring 122 for eutectic bonding. Therefore, the eutectic bonding material 124 may include germanium (Ge) and aluminum (Al).

In addition, the MEMS device layer 120 includes features such as trenches, cantilever beams, membranes, and proof masses to construct a MEMS device 126 such as inertial measurement unit (IMU), inertial sensor, pressure sensor, micro-fluidic device, other micro device or a combination thereof. The IMU includes an accelerometer, a gyroscope, other IMU device or a combination thereof.

As shown in FIG. 1, an opening is formed in the interconnect layer 110 to pass through the passivation layer 119 and the first dielectric layer 117, thereby exposing a portion 111A of the first metal layer 111 to correspond to the MEMS device 126. Some other openings are also formed in the interconnect layer 110 to pass through the passivation layer 119 and the first dielectric layer 117, thereby exposing some portions of the first metal layer 111 for bonding to the seal ring 122 with the eutectic bonding material 124.

Furthermore, the second substrate 103 is bonded to the MEMS device layer 120 through a bonding layer 127, for example, a silicon oxide layer. The second substrate 103 may be a silicon wafer and has a front surface 103F opposite to a back surface 103B. The second substrate 103 includes a cavity 105 formed therein and on the front surface 103F. The cavity 105 is located directly above the MEMS device 126. A stopper 104 may be positioned in the cavity 105, corresponding to the proof mass of the MEMS device 126. The stopper 104 is integrated into and has the same composition as the second substrate 103. A metal layer 107 may be formed on the back surface 103B of the second substrate 103. The metal layer 107 may be an aluminum layer for electromagnetic wave shielding such as radio frequency (RF) shielding and/or electrical grounding.

In addition, a wire 130 is disposed on the back surface 103B of the second substrate 103 and bonded to the portion 112B of the second metal layer 112. The wire 130 may be in direct contact with the metal layer 107, for example, an aluminum layer, on the second surface 103B of the second substrate 103. The thickness of the metal layer 107 may be greater than 0.9 µm. In the MEMS package 100, the wire 130 may be a copper (Cu) wire to replace a gold (Au) wire, thereby reducing the cost. The portion 112B of the second metal layer 112 includes a bond pad with a thickness greater than 0.9 µm, which is sufficiently thick for Cu wire bonding. Therefore, the thickness of the first metal layer 111 in the MEMS package 100 does not need to be increased.

Increasing the thickness of the first metal layer 111 will affect the eutectic bonding between the eutectic bonding material 124 and the first metal layer 111, such that the thickness of the eutectic bonding material 124, the thickness of the passivation layer 119 and the height of the seal ring 122 will all need to be increased. Increasing the thickness of the eutectic bonding material 124 will cause eutectic bonding alignment issue and easily squish the eutectic bonding material 124, which is unfavorable for electrode gap control. Increasing the thickness of the passivation layer 119 and the height of the seal ring 122 will also cause poor electrode gap control. Moreover, increasing the height of the seal ring 122 is unfavorable for fabrication. The MEMS packages 100 of the present disclosure can overcome the aforementioned issues, simplify fabrication, and reduce costs.

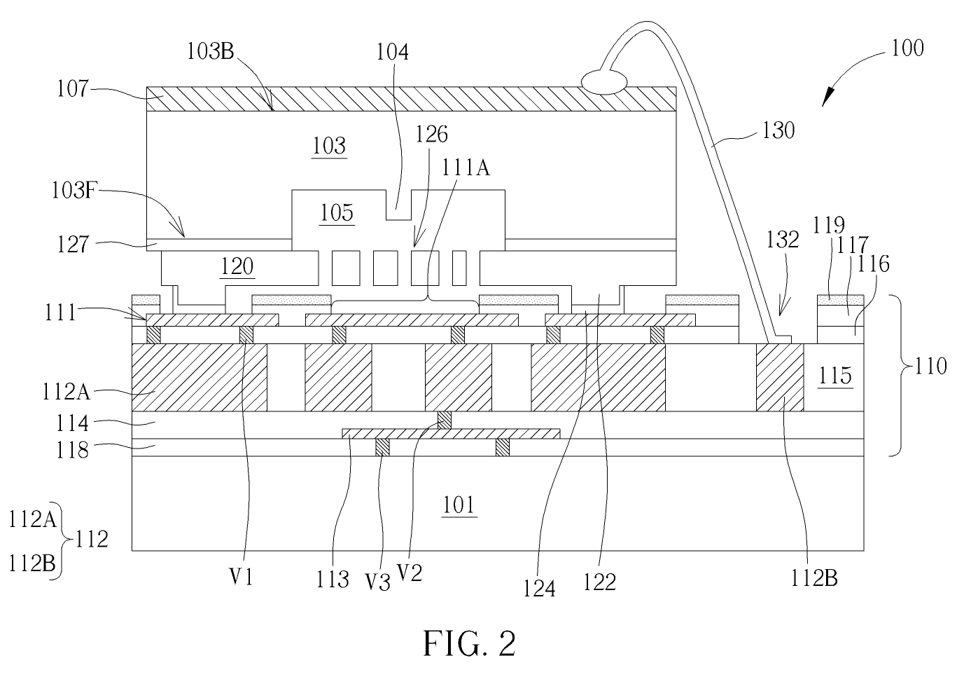

FIG. 2 is a schematic cross-sectional view of a MEMS package 100 according to another embodiment of the present disclosure. In the MEMS package 100 of FIG. 2, the opening 132 is formed in the interconnect layer 110 to pass through the passivation layer 119, the first dielectric layer 117 and the second dielectric layer 116, thereby exposing the portion 112B of the second metal layer 112 for wire bonding. The portion 112B of the second metal layer 112 includes a thick bond pad for Cu wire bonding with the wire 130. In this embodiment, the passivation layer 119 does not extend onto the sidewalls and the bottom surface of the opening 132. The exposed surface of the portion 112B of the second metal layer 112 and the bottom surface of the opening 132 may be on the same plane.

In some embodiments, as shown in FIG. 2, the interconnect layer 110 may further include a third metal layer 113, a fifth dielectric layer 118 and vias V3. The third metal layer 113 is disposed below and thinner than the second metal layer 112. The thickness of the third metal layer 113 may be the same as that of the first metal layer 111. The third metal layer 113 may be an aluminum (Al) layer or an aluminum-copper (AlCu) alloy layer. The fifth dielectric layer 118 is disposed below the fourth dielectric layer 114. The third metal layer 113 is formed on the fifth dielectric layer 118. The vias V2 are formed in the fourth dielectric layer 114. The vias V3 are formed in the fifth dielectric layer 118 and electrically connected to the third metal layer 113. The third metal layer 113 is electrically coupled to the CMOS transistors in the first substrate 101 through the vias V3. The details of other features of the MEMS package 100 in FIG. 2 may refer to the aforementioned descriptions of the MEMS device 100 in FIG. 1, and not repeated herein.

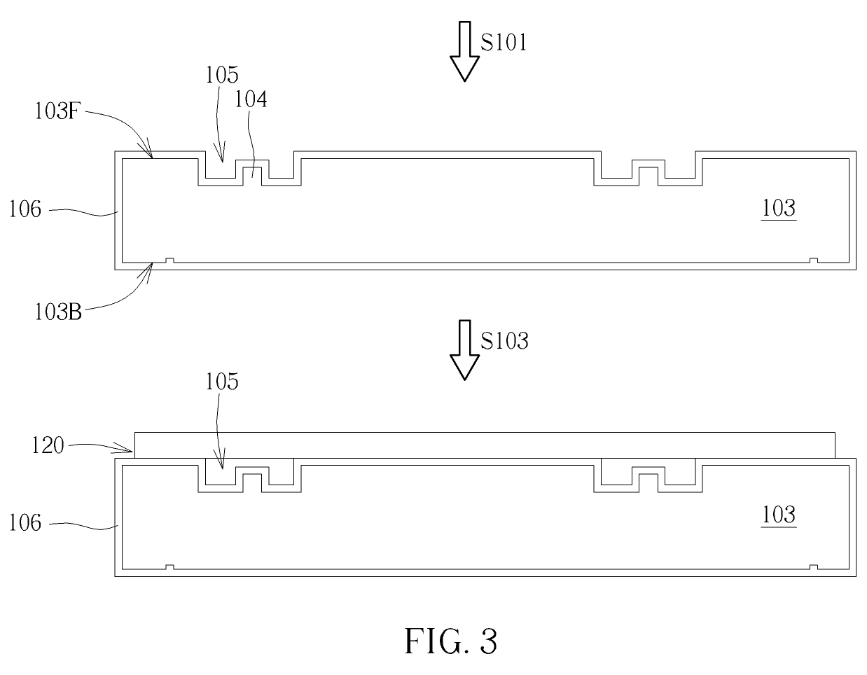

FIGS. 3, 4, 5, 6, 7, and 8 are schematic cross-sectional views of some stages of a method of fabricating a MEMS package 100 according to one embodiment of the present disclosure. Referring to FIG. 3, in step S101, firstly, a second substrate 103 such as a silicon wafer is provided. Then, cavities 105 and stoppers 104 are formed by etching in the second substrate 103 on the front surface 103F. Moreover, alignment marks are formed on the back surface 103B of the second substrate 103. Then, a bonding layer 106 is conformally formed on the front surface 103F, the sidewalls and the back surface 103B of the second substrate 103, further in the cavities 105 and on the stoppers 104 to wrap around the second substrate 103. The composition of the bonding layer 106 is, for example, silicon oxide and may be formed by a thermal oxidation or deposition.

Then, still referring to FIG. 3, in step S103, a device wafer such as a silicon wafer is thinned by back grinding and chemical-mechanical planarization (CMP) processes, and the edges of the thinned device wafer are trimmed, thereby providing a MEMS device layer 120 to be bonded to the second substrate 103 through the bonding layer 106 by fusion bonding. The MEMS device layer 120 covers the cavities 105 and the stoppers 104.

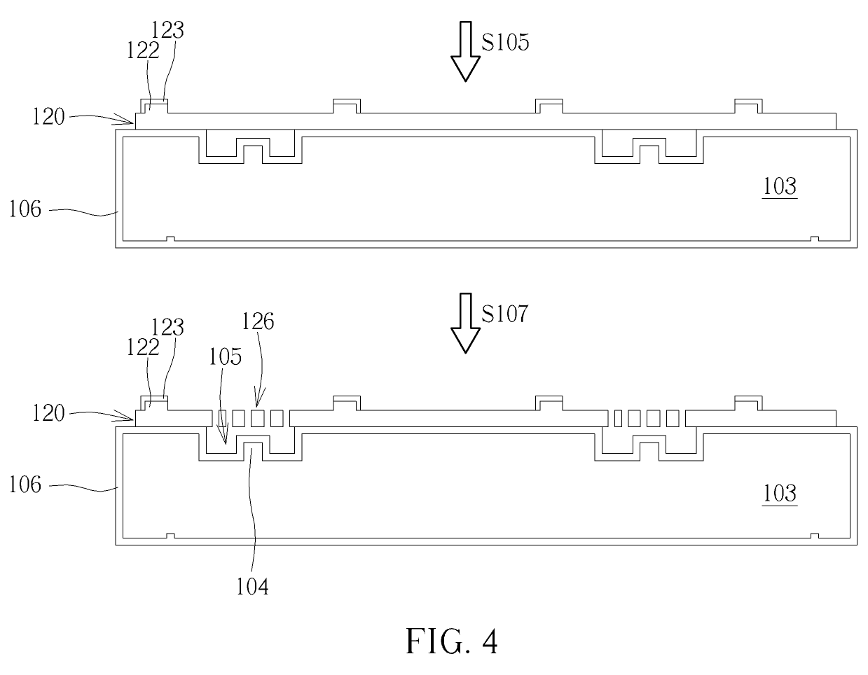

Next, referring to FIG. 4, in step S105, the MEMS device layer 120 is etched to form seal rings 122. Then, a bonding material 123 such as Ge is formed on the seal rings 122 by deposition and patterning processes. Still referring to FIG. 4, in step S107, the MEMS device layer 120 is patterned by etching to form MEMS devices 126. The seal ring 122 is located around the MEMS device 126. Multiple trenches of the MEMS device 126 are connected to the cavity 105.

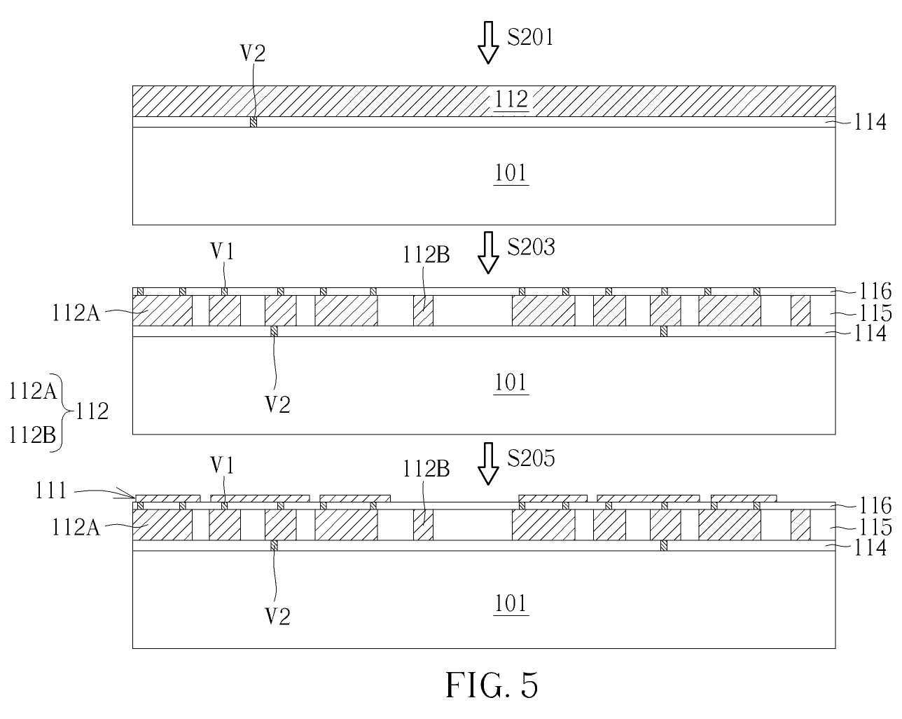

Referring to FIG. 5, in step S201, firstly, a first substrate 101 such as a CMOS wafer is provided. Then, a fourth dielectric layer 114, for example, silicon oxide layer is formed on the first substrate 101, and vias V2 are formed in the fourth dielectric layer 114 by etching and filling with tungsten (W). Then, a second metal layer 112, for example, AlCu layer is deposited on the fourth dielectric layer 114. The thickness of the second metal layer 112 is greater than 0.9 µm, for example, about 4.5 µm.

Next, still referring to FIG. 5, in step S203, the second metal layer 112 is patterned by etching to form a portion 112B and other portions 112A. A third dielectric layer 115 and a second dielectric layer 116, for example, silicon oxide layers are formed by deposition, thereby filling the spaces between the portions of the second metal layer 112 and covering the second metal layer 112. Vias V1 are formed in the second dielectric layer 116 by etching and filling with tungsten (W). The vias V1 are electrically connected to the portions 112A of the second metal layer 112. After the vias V1 are formed, CMP process is performed on the second dielectric layer 116.

Still referring to FIG. 5, in step S205, a first metal layer 111, for example, AlCu layer is formed on the planar surface of the second dielectric layer 116 by deposition and patterning processes. The thickness of the first metal layer 111 is less than 1 µm, for example, about 0.4 µm. The first metal layer 111 is electrically connected to the vias V1, and disposed above the portions 112A, not directly above the portion 112B of the second metal layer 112.

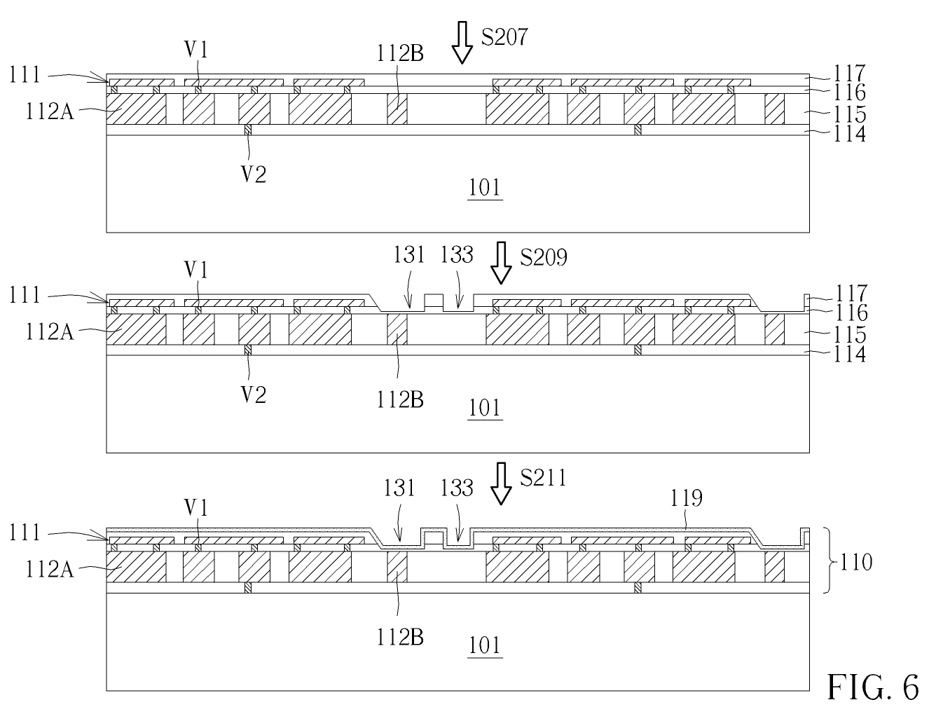

Next, referring to FIG. 6, in step S207, a first dielectric layer 117, for example, silicon oxide layer is deposited on the second dielectric layer 116 and covers the first metal layer 111. Then, CMP process is performed on the first dielectric layer 117.

Still referring to FIG. 6, in step S209, the first dielectric layer 117 is etched to form recesses 131 directly above the portions 112B of the second metal layer 112 and pre-cut lines 133. The recess 131 may have an inclined sidewall, and does not expose the portion 112B of the second metal layer 112. Then, still referring to FIG. 6, in step S211, a passivation layer 119, for example, silicon nitride layer is conformally formed by deposition on the first dielectric layer 117 and in the recesses 131 and the pre-cut lines 133.

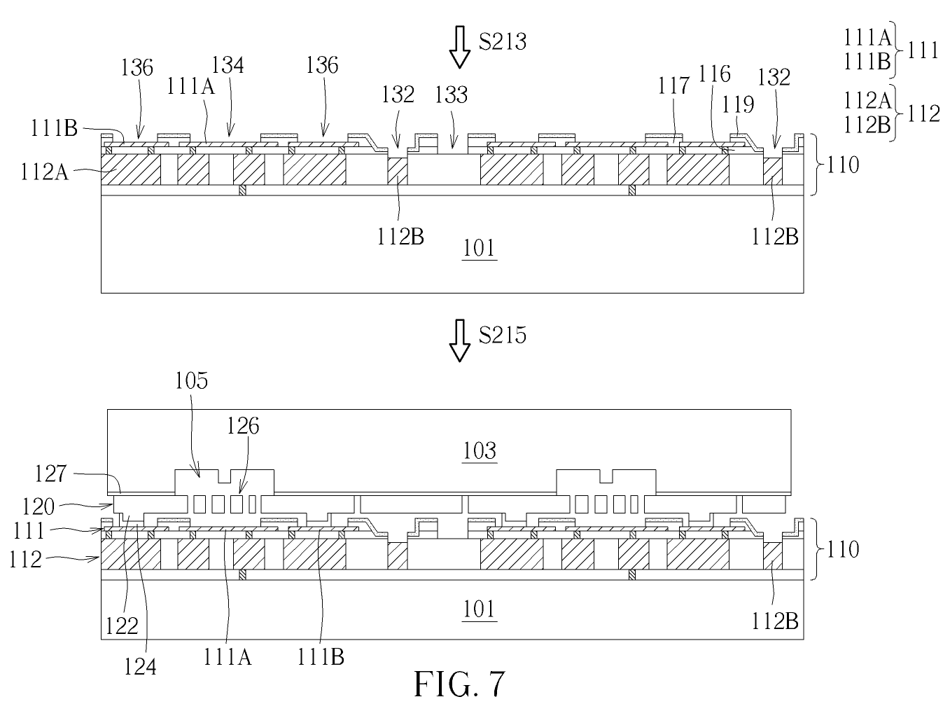

Next, referring to FIG. 7, in step S213, the passivation layer 119 in the recesses 131 and portions of the second dielectric layer 116 under the recesses 131 are etched to form openings 132, thereby exposing the portion 112B of the second metal layer 112 for wire bonding. Also, the passivation layer 119 in the pre-cut lines 133 and portions of the second dielectric layer 116 under the pre-cut lines 133 are etched. Moreover, the passivation layer 119 and the first dielectric layer 117 are etched to form openings 134 and openings 136, thereby exposing portions 111A and portions 111B of the first metal layer 111.

Still referring to FIG. 7, in step S215, firstly, portions of the bonding layer 106 in the cavities 105 and on the stoppers 104, on the sidewalls and the back surface 103B of the second substrate 103 as shown in step S107 are removed by vapor hydrogen fluoride (VHF) etching, thereby leaving a bonding layer 127 between the second substrate 103 and the MEMS device layer 120. Then, the seal ring 122 is bonded to the portions 111B of the first metal layer 111 with a eutectic bonding material 124, which includes Ge of the bonding material 123 and Al of the first metal layer 111. After the MEMS device layer 120 is bonded to the interconnect layer 110, the portion 111A of the first metal layer 111 is located directly below and corresponding to the MEMS device 126.

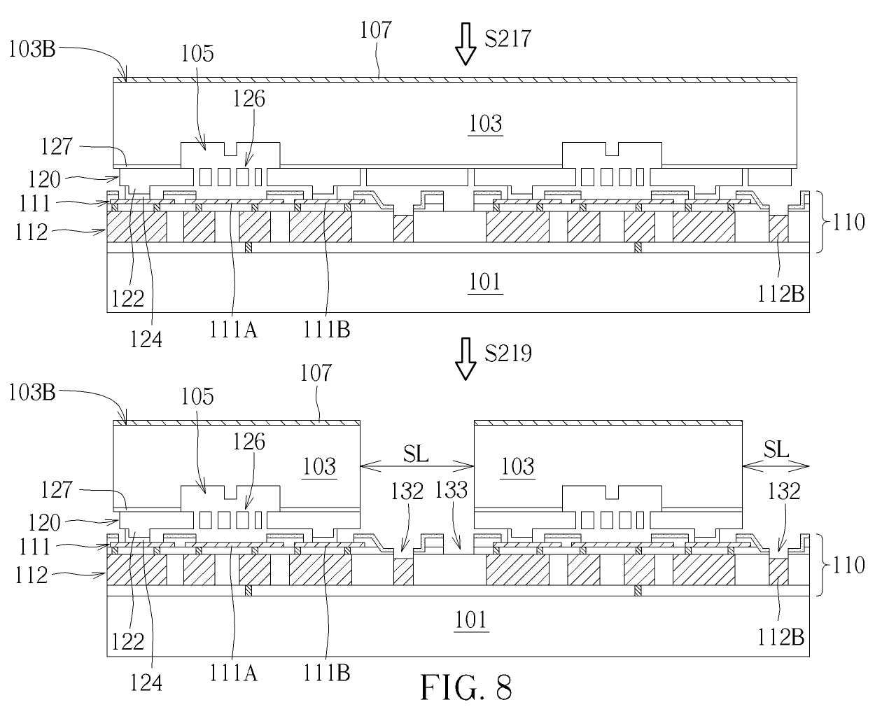

Next, referring to FIG. 8, in step S217, a metal layer 107, for example, Al layer is deposited on the back surface 103B of the second substrate 103. Then, still referring to FIG. 8, in step S219, parts of the second substrate 103 and parts of the MEMS device layer 120 at scribe lines SL are removed by blade saw. Thereafter, the interconnect layer 110 and the first substrate 101 are diced along the pre-cut lines 133. Then, a wire 130 is provided on the metal layer 107 and bonded to the portion 112B of the second metal layer 112 to complete the MEMS package 100 of FIG. 1.

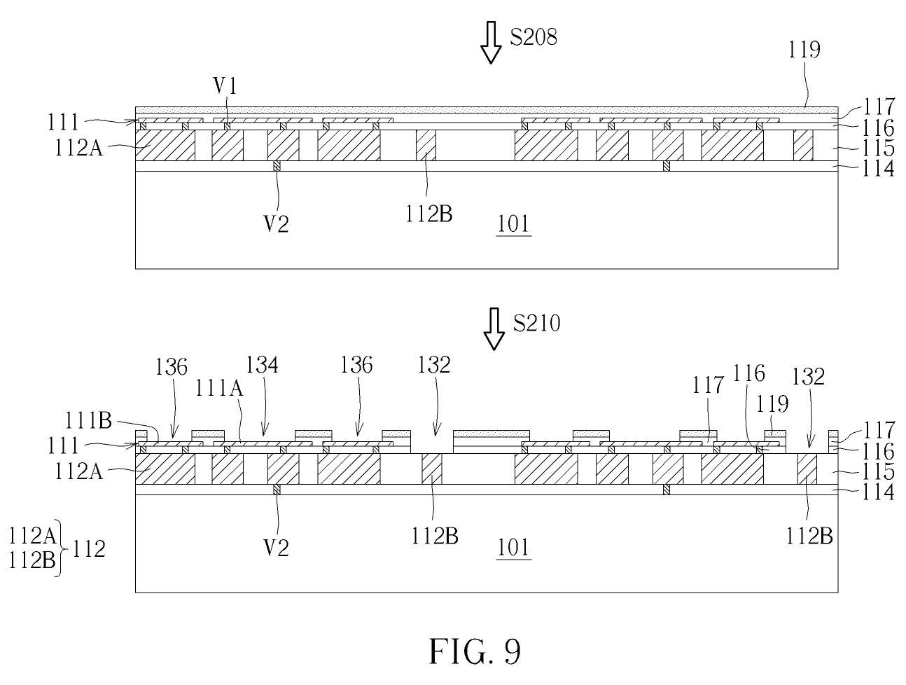

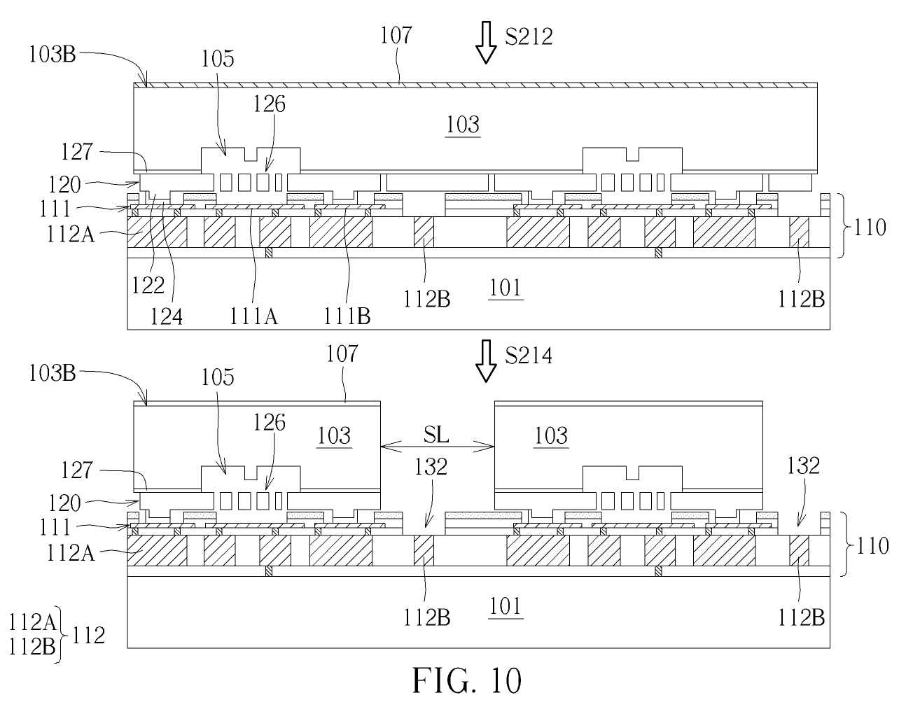

FIGS. 9 and 10 are schematic cross-sectional views of some intermediate stages of a method of fabricating a MEMS package 100 according to another embodiment of the present disclosure. Referring to FIG. 9, in step S208, after step S207 is completed, a passivation layer 119 is deposited on the planar surface of the first dielectric layer 117. Then, still referring to FIG. 9, in step S210, the passivation layer 119, the first dielectric layer 117 and the second dielectric layer 116 are etched to form openings 132, thereby exposing the portion 112B of the second metal layer 112. Moreover, the passivation layer 119 and the first dielectric layer 117 are etched to form openings 134 and openings 136, thereby exposing portions 111A and portions 111B of the first metal layer 111.

Next, referring to FIG. 10, in step S212, a metal layer 107, for example, Al layer is deposited on the back surface 103B of the second substrate 103. Then, still referring to FIG. 10, in step S214, parts of the second substrate 103 and parts of the MEMS device layer 120 at scribe lines SL are removed by blade saw. Thereafter, the interconnect layer 110 and the first substrate 101 are diced. Then, a wire 130 is provided on the metal layer 107 and bonded to the portion 112B of the second metal layer 112 to complete the MEMS package 100 of FIG. 2.

According to the embodiments of the present disclosure, the MEMS packages include a thick bond pad in the interconnect layer for copper wire bonding, thereby reducing the cost of the MEMS packages. The bond pad with thickness greater than 0.9 µm is provided from the second metal layer in the interconnect layer. The second metal layer is disposed below and thicker than the first metal layer. The interconnect layer provides the thick bond pad for good copper wire bonding without increasing the thickness of the first metal layer. Since the first metal layer is not thickened, the eutectic bonding material, the passivation layer and the seal ring do not need to be thickened. Therefore, the overall performance of the MEMS packages, such as eutectic bonding quality, eutectic bonding alignment control, eutectic bonding material squish control, electrode gap control, and device sensitivity, are at least maintained or improved. The probability of device shorting is also reduced by eutectic bonding material squish control. Moreover, the fabrication process of the interconnect layer with the thick bond pad is compatible with CMOS wafer fabrication.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A micro-electro-mechanical system (MEMS) package, comprising:
a first substrate;
an interconnect layer, disposed on the first substrate, wherein the interconnect layer comprises:
a first metal layer;
a second metal layer, disposed below and thicker than the first metal layer;
a first dielectric layer, disposed on the first metal layer;
a second dielectric layer, disposed between the first metal layer and the second metal layer; and
an opening, passing through the first dielectric layer and the second dielectric layer to expose a portion of the second metal layer;
a MEMS device layer, bonded to the interconnect layer; and
a second substrate, including a cavity and bonded to the MEMS device layer.

2. The MEMS package of claim 1, further comprising a wire disposed on the second substrate and bonded to the portion of the second metal layer, wherein the portion of the second metal layer includes a bond pad.

3. The MEMS package of claim 2, wherein the wire comprises a copper wire, and the second metal layer comprises an aluminum-copper alloy layer or an aluminum layer.

4. The MEMS package of claim 2, further comprising a metal layer disposed on a surface of the second substrate, wherein the wire is in direct contact with the metal layer.

5. The MEMS package of claim 4, wherein the metal layer comprises an aluminum layer.

6. The MEMS package of claim 1, wherein the first metal layer is not disposed directly above the portion of the second metal layer.

7. The MEMS package of claim 1, wherein a thickness of the second metal layer is 2 to 7 times a thickness of the first metal layer.

8. The MEMS package of claim 1, wherein a thickness of the second metal layer is greater than 0.9 µm and less than 5 µm.

9. The MEMS package of claim 1, wherein a thickness of the first metal layer is less than 1 µm and greater than 0.5 µm.

10. The MEMS package of claim 1, wherein the interconnect layer further comprises a passivation layer disposed on the first dielectric layer, and the opening passes through the passivation layer.

11. The MEMS package of claim 10, wherein an exposed surface of the portion of the second metal layer and a bottom surface of the opening are on the same plane.

12. The MEMS package of claim 1, wherein the interconnect layer further comprises a passivation layer disposed on the first dielectric layer, and the passivation layer is conformally extended on sidewalls and a portion of a bottom surface of the opening.

13. The MEMS package of claim 12, wherein an exposed surface of the portion of the second metal layer is lower than the portion of the bottom surface of the opening.

14. The MEMS package of claim 1, wherein the MEMS device layer comprises a seal ring bonded to the first metal layer with a eutectic bonding material.

15. The MEMS package of claim 14, wherein the eutectic bonding material comprises germanium and aluminum.

16. The MEMS package of claim 14, wherein the seal ring and the MEMS device layer have the same composition, and the seal ring is integrated into the MEMS device layer.

17. The MEMS package of claim 1, wherein the second metal layer has a uniform thickness in the interconnect layer.

18. The MEMS package of claim 1, wherein the first substrate includes a plurality of complementary metal oxide semiconductor (CMOS) transistors therein, and the interconnect layer is electrically coupled to the plurality of CMOS transistors.

19. The MEMS package of claim 1, wherein the MEMS device layer comprises an inertial measurement unit (IMU), and the IMU comprises an accelerometer, a gyroscope or a combination thereof.

20. The MEMS package of claim 1, wherein a portion of the first metal layer, corresponding to an area of the IMU, is exposed.
